(19) United States
(12) Patent Application Publication
(10) Pub. No.: US 2024/0423067 A1
(43) Pub. Date: Dec. 19, 2024

(54) PROTECTIVE LAYER AND DISPLAY APPARATUS INCLUDING THE SAME

(71) Applicant: Samsung Display Co., LTD., Yongin-si (KR)

(72) Inventors: Kyoungtae KIM, Yongin-si (KR); Hanjae KIM, Yongin-si (KR); Changmin PARK, Yongin-si (KR); Woojong SON, Yongin-si (KR)

(21) Appl. No.: 18/428,176

(22) Filed: Jan. 31, 2024

(30) Foreign Application Priority Data
Mar. 24, 2023 (KR) 10-2023-0039204
Jun. 27, 2023 (KR) 10-2023-0082895

(51) Int. Cl. H10K 59/80; H10K 102/00

(52) U.S. Cl. CPC H10K 59/8722; H10K 2102/311

(57) ABSTRACT

A display apparatus includes: a display panel including a substrate, a pixel circuit layer disposed on the substrate, and a display element layer disposed on the pixel circuit layer; a cover window disposed on the display panel to cover the display panel; and a protective layer disposed on the cover window to cover the cover window, where the protective layer includes polyethylene terephthalate and has a thickness of about 50 μm to about 75 μm.

This application claims priority to Korean Patent Application No. 10-2023-0039204, filed on Mar. 24, 2023, and Korean Patent Application No. 10-2023-0082895, filed on Jun. 27, 2023, and all the benefits accruing therefrom under 35 U.S.C. § 119, the contents of which in their entirety are herein incorporated by reference.

### BACKGROUND

### 1. Field

One or more embodiments relate to an apparatus, and more particularly, to a display apparatus including a protective layer.

### 2. Description of the Related Art

A Mobile electronic apparatus is widely used. As the mobile electronic apparatus, recently, a tablet personal computer (“PC”) has been widely used as well as a miniaturized electronic apparatus such as a mobile phone.

To support various functions, for example, to provide a user with visual information, such as images, the mobile electronic apparatus includes a display apparatus. As the parts configured to drive the display apparatus have been miniaturized, the proportion of the display apparatus in an electronic apparatus has been gradually increased and a structure that may be bent to form a preset angle with respect to a flat state has also been developed.

### SUMMARY

One or more embodiments include a protective layer configured to improve the quality of a surface of a display apparatus.

However, such a technical aspect is just an example, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes: a display panel including a substrate, a pixel circuit layer disposed on the substrate, and a display element layer disposed on the pixel circuit layer; a cover window disposed on the display panel to cover the display panel; and a protective layer disposed on the cover window to cover the cover window, where the protective layer includes polyethylene terephthalate and has a thickness of about 50 micrometers (μm) to about 75 μm.

The display apparatus may further include an adhesive layer disposed between the cover window and the protective layer such that the adhesive layer is in contact with the protective layer.

The thickness of the adhesive layer may be about 35 μm and about 75 μm.

The thickness of the protective layer may be about 65 μm to about 75 μm.

The adhesive layer may include a pressure-sensitive adhesive layer.

The display panel may be foldable around a folding axis, and the protective layer may include a flexible material.

According to one or more embodiments, a protective layer for protecting a cover window disposed on a display panel includes polyethylene terephthalate and has a thickness of about 50 μm to about 75 μm.

The thickness of the protective layer may be about 65 μm to about 75 μm.

The protective layer may include a flexible material.

These and/or other aspects will become apparent and more readily appreciated from the following detailed description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1 and 2 are schematic perspective views of a display apparatus according to an embodiment;

FIG. 3 is a schematic cross-sectional view of a portion of a display apparatus according to an embodiment;

FIG. 4 is a graph of surface quality of a display apparatus according to an embodiment; and

FIG. 5 is an equivalent circuit diagram of a pixel of a display apparatus according to an embodiment.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, where like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise. “About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the described order. As an example, two processes successively described may be simultaneously performed substantially and performed in the opposite order.

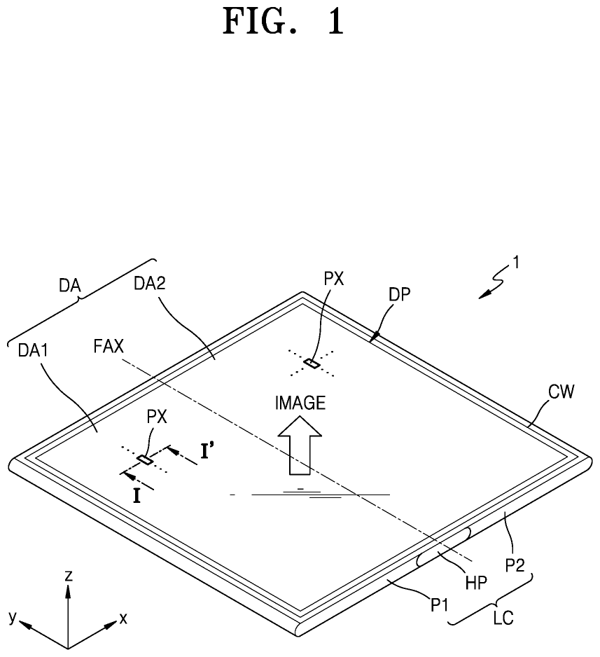

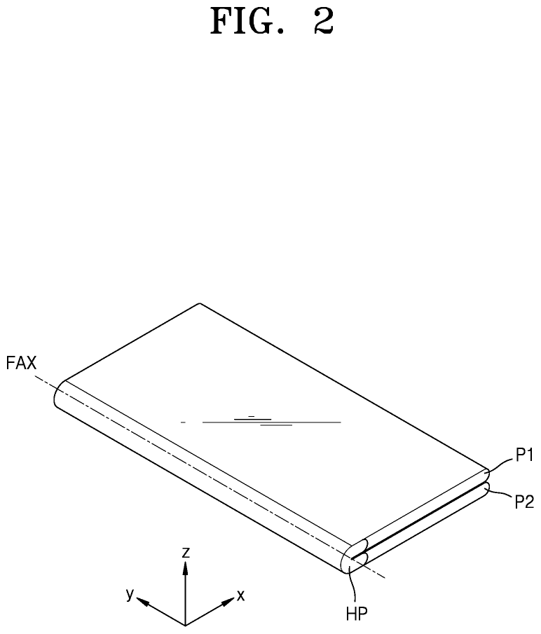

FIGS. 1 and 2 are schematic perspective views of a display apparatus 1 according to an embodiment.

Specifically, FIG. 1 shows the display apparatus 1 in an unfolded state, and FIG. 2 shows the display apparatus 1 in a folded state.

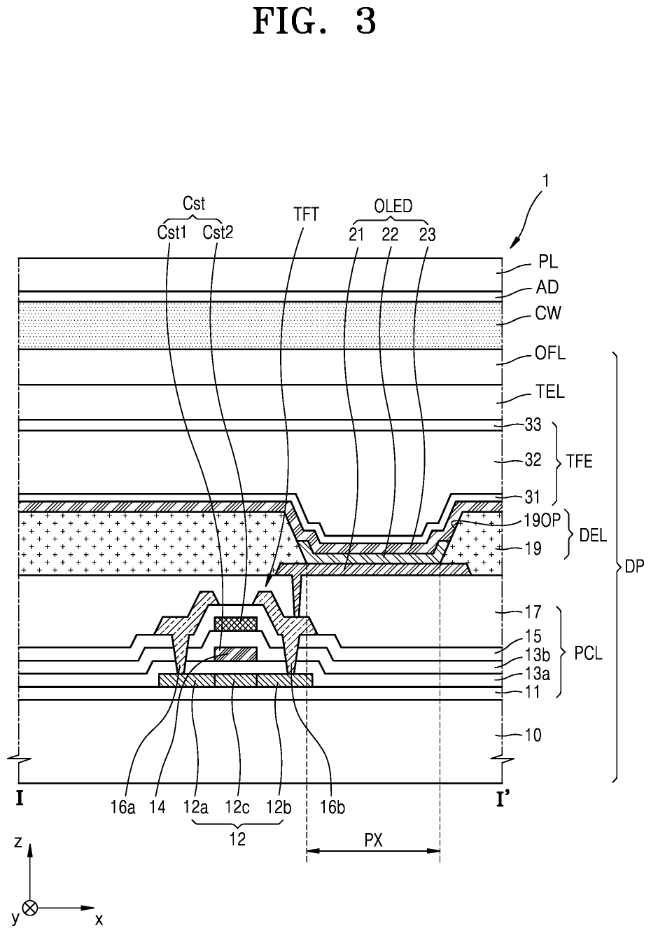

Referring to FIGS. 1 and 2, the display apparatus 1 may include a lower cover LC, a display panel DP, and a cover window CW. In addition, the display apparatus 1 may further include a protective layer PL (see FIG. 3). The protective layer PL (see FIG. 3) is described below in detail with reference to FIG. 3.

The lower cover LC may include a first part P1 and a second part P2 supporting the display panel DP. The lower cover LC may be folded around a folding axis FAX defined between the first part P1 and the second part P2. In an embodiment, the lower cover LC may further include a hinge part HP. The hinge part HP may be provided between the first part P1 and the second part P2.

The display panel DP may include a display area DA. The display panel DP may display images by using an array of a plurality of pixels PX arranged in the display area DA. Each of the pixels PX may be defined as an emission area from which light may be emitted by a light-emitting element electrically connected to a pixel circuit. In an embodiment, each pixel PX may be configured to emit red, green, or blue light. Alternatively, each pixel PX may be configured to emit red, green, blue, or white light.

A light-emitting element of the display panel DP may include an organic light-emitting diode, an inorganic light-emitting diode, a micro light-emitting diode, and/or a quantum-dot light-emitting diode. For convenience of description, although the case where a light-emitting element of the display panel DP includes an organic light-emitting diode is mainly described, the contents described below are not limited thereto and equally applicable to different types of light-emitting diodes.

The display area DA may include a first display area DA1 and a second display area DA2, where the first display area DA1 and the second display area DA2 are arranged on two opposite sides around the folding axis FAX crossing the display area DA, respectively. The first display area DA1 and the second display area DA2 may be disposed on the first part P1 and the second part P2 of the lower cover LC, respectively. The display panel DP may display a first image and a second image by using light emitted from the plurality of pixels PX arranged in the first display area DA1 and the second display area DA2. In an embodiment, the first image and the second image may be portions of one of images displayed by the display area DA of the display panel DP. In another embodiment, the display panel DP may be configured to display the first image and the second image which are independent images.

The display panel DP may be folded around the folding axis FAX. When the display panel DP is folded, the first display area DA1 and the second display area DA2 of the display panel DP may face each other.

Although it is shown in FIGS. 1 and 2 that the folding axis FAX extends in a y direction, the embodiment is not limited thereto. In another embodiment, the folding axis FAX may extend in an x direction crossing the y direction. Alternatively, the folding axis FAX may also extend in a direction crossing the x direction and the y direction.

In addition, although it is shown in FIGS. 1 and 2 that the folding axis FAX is one, the embodiment is not limited thereto. In another embodiment, the display panel DP may be folded plurality of times with respect to a plurality of folding axes FAX crossing the display area DA.

The cover window CW may be disposed on the display panel DP to cover the display panel DP. The cover window CW may be folded or warped according to external force without crack occurrence. When the display panel DP is folded around the folding axis FAX, the cover window CW may be folded together.

FIG. 3 is a schematic cross-sectional view of a portion of the display apparatus 1 according to an embodiment.

FIG. 3 may correspond to a cross-section of the display apparatus 1 taken along line I-I′ of FIG. 1.

Referring to FIG. 3, the display panel DP may have a stack structure including a substrate 10, a pixel circuit layer PCL, a display element layer DEL, a thin-film encapsulation layer TFE, a touch electrode layer TEL, and an optical functional layer OFL.

The substrate 10 may include glass or a polymer resin. In this case, the polymer resin may include at least one of polyethersulfone, polyarylate, polyetherimide, polyethylene naphthalate, polyethylene terephthalate, polyphenylene sulfide, polyimide, polycarbonate, cellulose tri acetate, cellulose acetate propionate, and the like.

The pixel circuit layer PCL may be disposed on the substrate 10. It is shown that the pixel circuit layer PCL includes a thin-film transistor TFT, a buffer layer 11, a first insulating layer 13a, a second insulating layer 13b, a third insulating layer 15, and a planarization layer 17 under and/or on elements of the thin-film transistor TFT.

The buffer layer 11 may block penetration of foreign materials, moisture, or external air from below the substrate 10 and provide a flat surface on the substrate 10. The buffer layer 11 may include an inorganic insulating material such as silicon nitride, silicon oxynitride, and silicon oxide, and include a single layer or a multi-layer including the above inorganic insulating materials.

The thin-film transistor TFT on the buffer layer 11 may include a semiconductor layer 12, and the semiconductor layer 12 may include polycrystalline silicon. Alternatively, the semiconductor layer 12 may include amorphous silicon, an oxide semiconductor, or an organic semiconductor. The semiconductor layer 12 may include a channel region 12c, a drain region 12a, and a source region 12b, and the drain region 12a and the source region 12b may be on two opposite sides of the channel region 12c, respectively. A gate electrode 14 may overlap the channel region 12c in the z-axis.

The gate electrode 14 may include a low-resistance metal material. The gate electrode 14 may include a conductive material including molybdenum (Mo), aluminum (Al), copper (Cu), and titanium (Ti) and have a single-layered structure or a multi-layered structure including the above materials.

The first insulating layer 13a may be disposed between the semiconductor layer 12 and the gate electrode 14. The first insulating layer 13a may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

The second insulating layer 13b may cover the gate electrode 14. The second insulating layer 13b may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO).

An upper electrode Cst2 of a storage capacitor Cst may be disposed on the second insulating layer 13b. The upper electrode Cst2 may overlap at least a portion of the gate electrode 14 disposed therebelow in the z-axis. The gate electrode 14 and the upper electrode Cst2 overlapping each other with the second insulating layer 13b therebetween in the z-axis may constitute the storage capacitor Cst. That is, the gate electrode 14 may serve as a lower electrode Cst1 of the storage capacitor Cst.

As described above, the storage capacitor Cst may overlap the thin-film transistor TFT in the z-axis. Alternatively, in another embodiment, the storage capacitor Cst may not overlap the thin-film transistor TFT in the z-axis. That is, the lower electrode Cst1 of the storage capacitor Cst may be an element separate from the gate electrode 14 and be separated from the gate electrode 14.

The upper electrode Cst2 may include aluminum (AI), platinum (Pt), palladium (Pd), silver (Ag), magnesium (Mg), gold (Au), nickel (Ni), neodymium (Nd), iridium (Ir), chrome (Cr), calcium (Ca), molybdenum (Mo), titanium (Ti), tungsten (W), and/or copper (Cu), and include a single layer or a multi-layer including the above materials.

The third insulating layer 15 may cover the upper electrode Cst2. The third insulating layer 15 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO). The third insulating layer 15 may include a single layer or a multi-layer including the inorganic insulating material.

A drain electrode 16a and a source electrode 16b may each be disposed on the third insulating layer 15. The drain electrode 16a and the source electrode 16b may be connected to the drain region 12a and the source region 12b, respectively, through contact holes defined in insulating layers therebelow. The drain electrode 16a and the source electrode 16b may each include a material having a high conductivity. The drain electrode 16a and the source electrode 16b may each include a conductive material including molybdenum (Mo), aluminum (AI), copper (Cu), and titanium (Ti) and have a single-layered structure or a multi-layered structure. In an embodiment, the drain electrode 16a and the source electrode 16b may each have a multi-layered structure of Ti/Al/Ti.

The planarization layer 17 may include an organic insulating material. The planarization layer 17 may include an organic insulating material including a general-purpose polymer such as polymethylmethacrylate (“PMMA”) or polystyrene (“PS”), polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, or a blend thereof.

The display element layer DEL may be disposed on the pixel circuit layer PCL having the above structure. The display element layer DEL may include an organic light-emitting diode OLED as a light-emitting element. The organic light-emitting diode OLED may have a stack structure of a first electrode 21, an emission layer 22, and a second electrode 23. The first electrode 21 of the organic light-emitting diode OLED may be electrically connected to the thin-film transistor TFT through a contact hole defined in the planarization layer 17.

The first electrode 21 may include a conductive oxide such as indium tin oxide (“ITO”), indium zinc oxide (“IZO”), zinc oxide (ZnO), indium oxide (In₂O₃), indium gallium oxide (“IGO”), or aluminum zinc oxide (“AZO”). In an embodiment, the first electrode 21 may include a reflective layer including silver (Ag), magnesium (Mg), aluminum (AI), platinum (Pt), palladium (Pd), gold (Au), nickel (Ni), neodymium (Nd), iridium (Ir), chrome (Cr), or a compound thereof. Alternatively, in an embodiment, the first electrode 21 may further include a layer on/under the reflective layer, the layer including ITO, IZO, ZnO, or In₂O₃.

A pixel-defining layer 19 may be disposed on the first electrode 21, the pixel-defining layer 19 defining therein an opening 19OP exposing at least a portion of the first electrode 21. The pixel-defining layer 19 may include an organic insulating material and/or an inorganic insulating material. The opening 19OP may define an emission area of light emitted from the organic light-emitting diode OLED. As an example, the size/width of the opening 19OP may correspond to the size/width of the emission area. Accordingly, the size and/or width of the pixel PX may depend on the size and/or width of the opening 19OP of the pixel-defining layer 19.

The emission layer 22 may be disposed in the opening 19OP of the pixel-defining

layer 19. The emission layer 22 may include a polymer organic material or a low-molecular weight organic material configured to emit light having a preset color. Alternatively, the emission layer 22 may include an inorganic emission material or quantum dots.

Although omitted in FIG. 3, a first functional layer and a second functional layer may be respectively disposed under and on the emission layer 22. In an embodiment, the first functional layer may include, for example, a hole transport layer (“HTL”), or include an HTL and a hole injection layer (“HIL”). The second functional layer may include an electron transport layer (“ETL”) and/or an electron injection layer (“EIL”). However, the embodiment is not limited thereto. In another embodiment, the first functional layer and the second functional layer may be selectively disposed on and under the emission layer 22, respectively.

Like the second electrode 23 described below, the first functional layer and/or the second functional layer may be common layers covering entirety of the substrate 10.

The second electrode 23 may be disposed over the first electrode 21 and may overlap the first electrode 21 in the z-axis. The second electrode 23 may include a conductive material having a low work function. As an example, the second electrode 23 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), or an alloy thereof. Alternatively, the second electrode 23 may further include a layer on the (semi) transparent layer, the layer including ITO, IZO, ZnO, or In₂O₃. The second electrode 23 may be formed as one body to cover entirety of the substrate 10.

An encapsulation member may be disposed on the display element layer DEL. In an embodiment, the encapsulation member may be provided as the thin-film encapsulation layer TFE. The thin-film encapsulation layer TFE may be disposed on the display element layer DEL and may cover the display element layer DEL. The thin-film encapsulation layer TFE may include at least one inorganic encapsulation layer and at least one organic encapsulation layer. In an embodiment, the thin-film encapsulation layer TFE may include a first inorganic encapsulation layer 31, an organic encapsulation layer 32, and a second inorganic encapsulation layer 33 that are sequentially stacked. In another embodiment, the encapsulation member may be provided as an encapsulation substrate.

The first inorganic encapsulation layer 31 and the second inorganic encapsulation layer 33 may include at least one inorganic material from among aluminum oxide, titanium oxide, tantalum oxide, hafnium oxide, zinc oxide, silicon oxide, silicon nitride, and silicon oxynitride. The organic encapsulation layer 32 may include a polymer-based material. The polymer-based material may include an acryl-based resin, an epoxy-based resin, polyimide, and polyethylene. In an embodiment, the organic encapsulation layer 32 may include acrylate. The organic encapsulation layer 32 may be formed by hardening a monomer or coating a polymer.

The touch electrode layer TEL including touch electrodes may be disposed on the thin-film encapsulation layer TFE, and the optical functional layer OFL may be disposed on the touch electrode layer TEL. The touch electrode layer TEL may obtain coordinate information corresponding to an external input, for example, a touch event. The optical functional layer OFL may reduce the reflectivity of light (external light) incident toward the display apparatus 1 from the outside, and improve the color purity of light emitted from the display apparatus 1.

In an embodiment, the optical functional layer OFL may include a phase retarder and/or a polarizer. The phase retarder may include a film-type phase retarder or a liquid crystal-type phase retarder. The phase retarder may include a λ/2 phase retarder and/or a λ/4 phase retarder. The polarizer may include a film-type polarizer or a liquid crystal-type polarizer. The film-type polarizer may include a stretchable synthetic resin film, and the liquid crystal-type polarizer may include liquid crystals arranged in a predetermined arrangement. Each of the phase retarder and the polarizer may further include a protective film.

In an embodiment, the optical functional layer OFL may include a destructive interference structure. The destructive interference structure may include a first reflection layer and a second reflection layer disposed on different layers, respectively. First-reflected light and second-reflected light reflected by the first reflection layer and the second reflection layer, respectively, may destructively interfere and thus the reflectivity of external light may be reduced.

An adhesive member may be disposed between the touch electrode layer TEL and the optical functional layer OFL. For the adhesive member, a general member known in the art may be employed without limitation. As an example, the adhesive member may be a pressure sensitive adhesive (“PSA”).

The cover window CW may be disposed on the display panel DP. The cover window CW may be adhered to the display panel DP by the adhesive member. In an embodiment, the adhesive member may be, for example, a PSA.

The cover window CW may have a high transmittance to transmit light emitted from the display panel DP. In addition, the cover window CW may have a thin thickness to reduce the weight of the display apparatus 1 and have strong strength and hardness to protect the display panel DP from external impact. Here, the thickness is measured in the z-axis (i.e., thickness direction).

The protective layer PL may be disposed on the cover window CW. The protective layer PL may cover the cover window CW and protect the cover window CW. The protective layer PL may include polyethylene terephthalate (“PET”). Although not shown in FIG. 3, the protective layer PL may include a hard-coated layer. The protective layer PL may include a flexible material. Accordingly, as the display panel DP is folded, the protective layer PL may be folded together.

An adhesive layer AD may be disposed between the cover window CW and the protective layer PL. The adhesive layer AD may be in contact with the cover window CW and the protective layer PL. Accordingly, the adhesive layer AD may attach the cover window CW and the protective layer PL to each other. The adhesive layer AD may be a pressure-sensitive adhesive layer. In another embodiment, a separate protective member (not shown) may be disposed on the cover window CW. In this case, the adhesive layer AD may be disposed between the separate protective member (not shown) and the protective layer PL to attach the separate protective member (not shown) and the protective layer PL to each other.

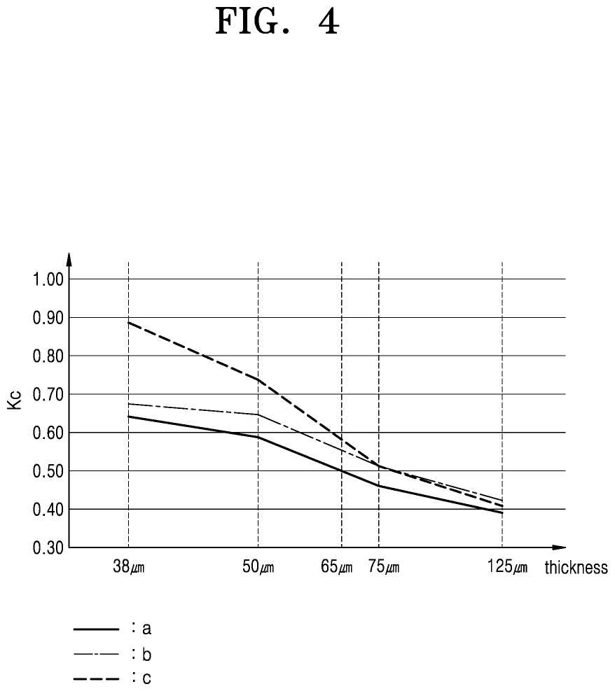

FIG. 4 is a graph of the surface quality of a display apparatus according to an embodiment.

Referring to FIGS. 3 and 4, a relationship between the thickness of the protective layer PL and the surface quality of the display apparatus 1 may be known.

In FIG. 4, a horizontal axis denotes the thickness of the protective layer PL, and a vertical axis denotes a Kc value of the display apparatus 1. In addition, a graph a is a graph in the case where the thickness of the protective layer PL is about 75 micrometers (μm), a graph b is a graph in the case where the thickness of the protective layer PL is about 50 μm, and a graph c is a graph in the case where the thickness of the protective layer PL is about 35 μm.

The Kc value is a curvature parameter measured for waviness having a wavelength range of about 1.0 millimeter (mm) to about 3.0 mm formed in the display apparatus 1 by phase stepped deflectometry (“PSD”).

In the graph shown in FIG. 4, the Kc value was measured using Optimap™ PSD by Rhopoint Co.

When the Kc value of the display apparatus 1 is small, it may be interpreted that a change in curvature at each point on the surface of the display apparatus 1 is small. When a change in curvature is small, it may be interpreted that a pattern changing periodically such as wavy patterns is small, and thus, when the Kc value is small, the surface quality of the display apparatus 1 may be greater than the case where the Kc value is large.

Referring to FIG. 4, it is known that, when the thickness of the protective layer PL increases, the Kc value is reduced. That is, when the thickness of the protective layer PL increases, the surface quality improves, but the thickness of the display apparatus 1 may excessively increase. Accordingly, the thickness of the protective layer PL is desirable to be set by taking into account a target surface quality of the display apparatus 1 and the thickness of the display apparatus 1.

Referring to the graph a, graph b, and graph c, with the boundary when the thickness of the protective layer PL is about 50 μm, the absolute value of the slope of the Kc value increases when the thickness of the protective layer PL exceeds 50 μm. That is, with the boundary when the thickness of the protective layer PL is about 50 μm, as the thickness of the protective layer PL increases, the surface quality of the display apparatus 1 may rapidly improve.

In contrast, with the boundary when the thickness of the protective layer PL is about 75 μm, when the thickness of the protective layer PL exceeds 75 μm, an absolute value of the slope of the Kc value is reduced. That is, with the boundary when the thickness of the protective layer PL is about 75 μm, as the thickness of the protective layer PL increases, the degree of improvement in the surface quality of the display apparatus 1 may be reduced.

Accordingly, when the thickness of the protective layer PL is about 50 μm to about 75 μm, the surface quality of the display apparatus 1 may be high compared to the thickness of the protective layer PL. Accordingly, the thickness of the protective layer PL may be about 50 μm to about 75 μm.

In another embodiment, the thickness of the adhesive layer AD may be about 35 μm to about 75 μm. In addition, the thickness of the protective layer PL may be about 65 μm to about 75 μm. In an embodiment, the Kc value of the display apparatus 1 may be 0.5 or less. In the case where the protective layer PL and the adhesive layer AD are not present, the Kc value of the display apparatus 1 is measured to be about 0.5. Accordingly, in an embodiment, the Kc value may be less than or equal to the Kc value in a case where the protective layer PL and the adhesive layer AD are not present.

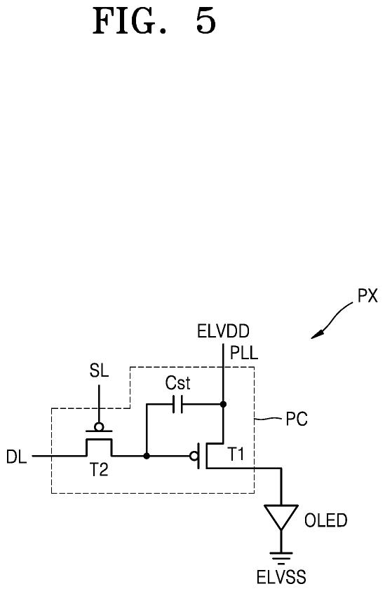

FIG. 5 is an equivalent circuit diagram of a pixel of the display apparatus according to an embodiment.

Referring to FIG. 5, one pixel PX may include a pixel circuit PC and an organic light-emitting diode OLED as a display element connected to the pixel circuit PC. The pixel circuit PC may include a first thin-film transistor T1, a second thin-film transistor T2, and a storage capacitor Cst. In an embodiment, each pixel PX may be configured to emit, for example, red, green, or blue light, or emit red, green, blue, or white light by using the organic light-emitting diode OLED.

The second thin-film transistor T2 is a switching thin-film transistor, may be connected to a scan line SL and a data line DL, and configured to transfer a data voltage to the first thin-film transistor T1 based on a switching voltage, where the data voltage is input from the data line DL, and the switching voltage is input from the scan line SL. The storage capacitor Cst may be connected to the second thin-film transistor T2 and a driving voltage line PLL and configured to store a voltage corresponding to a difference between a voltage transferred from the second thin-film transistor T2 and the driving voltage ELVDD supplied to the driving voltage line PLL.

The first thin-film transistor T1 is a driving thin-film transistor, may be connected to the driving voltage line PLL and the storage capacitor Cst, and configured to control a driving current according to the voltage stored in the storage capacitor Cst, the driving current flowing from the driving voltage line PL to the organic light-emitting diode OLED. The organic light-emitting diode OLED may be configured to emit light having a preset brightness corresponding to the driving current. The opposite electrode (e.g., a cathode) of the organic light-emitting diode OLED may be configured to receive the common voltage ELVSS.

Although it is described with reference to FIG. 5 that the pixel circuit PC includes two thin-film transistors and one storage capacitor, the embodiment is not limited thereto. The number of thin-film transistors and the number of storage capacitors may be variously changed according to the design of the pixel circuit PC. As an example, the pixel circuit PC may further include four or more thin-film transistors as well as the two thin-film transistors.

According to embodiments, the surface quality compared to the thickness in the display apparatus may be high.

Effects of the disclosure are not limited to the above-mentioned effects and other effects not mentioned may be clearly understood by those of ordinary skill in the art from the following claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel including a substrate, a pixel circuit layer disposed on the substrate, and a display element layer disposed on the pixel circuit layer;
a cover window disposed on the display panel to cover the display panel; and
a protective layer disposed on the cover window to cover the cover window,
wherein the protective layer includes polyethylene terephthalate and has a thickness of about 50 micrometers (μm) to about 75 μm.

2. The display apparatus of claim 1, further comprising an adhesive layer disposed between the cover window and the protective layer such that the adhesive layer is in contact with the protective layer.

3. The display apparatus of claim 2, wherein a thickness of the adhesive layer is about 35 μm to about 75 μm.

4. The display apparatus of claim 3, wherein the thickness of the protective layer is about 65 μm to about 75 μm.

5. The display apparatus of claim 2, wherein the adhesive layer includes a pressure-sensitive adhesive layer.

6. The display apparatus of claim 1, wherein the display panel is foldable around a folding axis, and the protective layer includes a flexible material.

7. A protective layer for protecting a cover window disposed on a display panel, the protective layer comprising polyethylene terephthalate, wherein the protective layer has a thickness of about 50 μm to about 75 μm.

8. The protective layer of claim 7, wherein the thickness of the protective layer is about 65 μm to about 75 μm.

9. The protective layer of claim 7, wherein the protective layer includes a flexible material.

10. The display apparatus of claim 4, wherein a curvature parameter measured for waviness having a wavelength range of about 1.0 millimeter (mm) to about 3.0 mm formed in the display apparatus by phase stepped deflectometry (PSD) is 0.5 or less.
